(19) United States
(12) Patent Application Publication
(10) Pub. No.: US 2025/0294887 A1
(43) Pub. Date: Sep. 18, 2025

(54) SELF-ALIGNED ISOLATION LAYER FOR STACKED FIELD-EFFECT TRANSISTORS

(71) Applicant: International Business Machines Corporation, Armonk, NY (US)

(72) Inventors: Jingyun Zhang, Albany, NY (US); Teresa J. Wu, Rexford, NY (US); DOMINGO FERRER, Clifton Park, NY (US); Prabudhya Roy Chowdhury, Albany, NY (US); Debarghya Sarkar, Latham, NY (US); Abir Shadman, Albany, NY (US); Utkarsh Bajpai, Delmar, NY (US)

(21) Appl. No.: 18/607,617

(22) Filed: Mar. 18, 2024

(51) Int. Cl. H01L 27/02; H01L 21/764; H01L 27/088; H01L 29/66

(52) U.S. Cl. CPC H10D 89/10; H01L 21/764; H10D 64/017; H10D 84/83

(57) ABSTRACT

A semiconductor structure that includes the top field-effect transistor (FET) on a portion of the bottom FET. The semiconductor structure includes the middle dielectric isolation where the middle dielectric isolation is over the top surface of the gate of the bottom FET. The isolation layer connects the sidewalls of adjacent portions of the middle dielectric isolation. The isolation layer vertically separates one or more top source/drains of the top FET from one or more bottom source/drains of the bottom FET. A first air gap is over the middle portion of the bottom source/drain and between the middle portion of the bottom source/drain and the middle portion of the isolation. A second air gap is below the middle portion of the top source/drain and between the middle portion of the top source/drain and the middle portion of the isolation layer.

### BACKGROUND

The disclosure generally relates to semiconductor structures, and more specifically, to a method of forming stacked field-effect transistors (stacked FETs) and the resulting structures.

The amount of data we process is rapidly increasing at a rate higher than that of Moore's law. Increasing system performance requirements, driven at least in part by the increasing use of artificial intelligence, continue to drive tighter pitches in semiconductor devices and smaller semiconductor chips. With increasing demands to reduce the dimensions of transistor devices, nanosheet field-effect transistors (FETs) help achieve a reduced device footprint while maintaining device performance. A nanosheet FET device contains one or more portions of layers of semiconductor channel material having a vertical thickness that is substantially less than its width. A typical nanosheet FET includes a plurality of stacked nanosheets extending between a pair of source/drain epitaxial regions. The nanosheet FET device may be a gate-all-around device in which a gate surrounds the channels of the nanosheet FET devices. The gate-all-around (GAA) nanosheet metal-oxide-semiconductor field-effect transistor (MOSFET) structures have been recognized as excellent candidates to achieve improved power performance and area scaling compared to the current FinFET technologies. Specifically, nanosheet-based semiconductor structures such as GAA nanosheet MOSFETs provide high drive currents due to wide effective channel width (Weff) while maintaining short-channel control. Further advances in semiconductor device stacking include the emergence of complementary field-effect transistors (CFET) is composed of two stacked complementary FETs with different polarities. The CFET includes a p-type FET (PFET) and an n-type FET (NFET) that are vertically stacked. CFETs can provide both device area reductions and device electrical performance improvements with the stacking of different polarity devices.

### SUMMARY

The following presents a summary to provide a basic understanding of one or more embodiments of the disclosure. This summary is not intended to identify key elements or delineate any scope of the particular embodiments or any scope of the claims.

Aspects of the disclosed invention relate to a semiconductor structure that includes. an isolation layer contacting portions of the top source/drain and the bottom source/drain where an air gap is between the middle portion of each of the top source/drain, the bottom source/drain, and the isolation layer.

Aspects of the disclosed invention relate to a semiconductor structure that includes the top field-effect transistor (FET) on a portion of the bottom FET. The semiconductor structure includes the middle dielectric isolation where the middle dielectric isolation is over the top surface of the gate of the bottom FET. The isolation layer connects the sidewalls of adjacent portions of the middle dielectric isolation. The isolation layer vertically separates one or more top source/drains of the top FET from one or more bottom source/drains of the bottom FET.

Aspects of the disclosed invention relate to a method of recessing portions of a nanosheet stack after forming the nanosheet stack on a substrate. The method includes forming dummy gates. The method includes the selective growth of an isolation layer from the sidewalls of the middle dielectric isolation using a selective atomic layer deposition process. The method includes trimming the isolation layer. The method includes using epitaxy to grow the first type source/drains from a plurality of channels above and below the isolation layer where an air gap is created between the first type source/drains and the middle portion of the isolation layer. The method includes removing portions of the first type source/drains above the isolation layer. The method includes forming a second type source/drain above the exposed portions of the isolation layer where an air gap forms between the middle portion of the isolation layer and the second type source/drains. The method includes forming replacement metal gates and removing the exposed portions of the isolation layer. The method includes forming a source/drain contact directly on each of the first type source/drains and forming a source/drain contact directly on each of the exposed surfaces of the second type source/drains.

### BRIEF DESCRIPTION OF THE DRAWINGS

The above and other aspects, features, and advantages of various embodiments of the present invention will be more apparent from the following description taken in conjunction with the accompanying drawings.

FIG. 1 depicts a top view of an illustration of a semiconductor design of an advanced semiconductor device, in accordance with an embodiment of the present invention.

FIG. 2A depicts a cross-sectional view A-A of a semiconductor structure after dummy gate formation and nanosheet stack recess, in accordance with an embodiment of the present invention.

FIG. 2B depicts a cross-sectional view B-B of the semiconductor structure after dummy gate formation and nanosheet stack recess, in accordance with an embodiment of the present invention.

FIG. 2C depicts a cross-sectional view C-C of the semiconductor structure after dummy gate formation and nanosheet stack recess, in accordance with an embodiment of the present invention.

FIG. 3A depicts a cross-sectional view Y1-Y1 of the semiconductor structure after selective growth of the isolation layer and isolation layer trimming, in accordance with an embodiment of the present invention.

FIG. 3B depicts a cross-sectional view Y2-Y2 of the semiconductor structure after selective growth of the isolation layer and isolation layer trimming, in accordance with an embodiment of the present invention.

FIG. 4A depicts a cross-sectional view Y1-Y1 of the semiconductor structure after epitaxial growth of source/drains, in accordance with an embodiment of the present invention.

FIG. 4B depicts a cross-sectional view Y2-Y2 of the semiconductor structure after epitaxial growth of source/drains, in accordance with an embodiment of the present invention.

FIG. 5A depicts a cross-sectional view Y1-Y1 of the semiconductor structure after the top source/drain etch back, in accordance with an embodiment of the present invention.

FIG. 5B depicts a cross-sectional view Y2-Y2 of the semiconductor structure after the top source/drain etch back depicted in FIG. 5A, in accordance with an embodiment of the present invention.

FIG. 6A depicts a cross-sectional view Y1-Y1 of the semiconductor structure after the top source/drain growth, in accordance with an embodiment of the present invention.

FIG. 6B depicts a cross-sectional view Y2-Y2 of the semiconductor structure after the top source/drain growth depicted in FIG. 6A, in accordance with an embodiment of the present invention.

FIG. 7 is a top view of the semiconductor structure after forming replacement metal gates and source/drain contacts, in accordance with an embodiment of the present invention.

FIG. 7A depicts a cross-sectional view Y1-Y1 of the semiconductor structure after forming replacement metal gates and source/drain contacts, in accordance with an embodiment of the present invention.

FIG. 7B depicts a cross-sectional view Y2-Y2 of the semiconductor structure after forming replacement metal gates and source/drain contacts, in accordance with an embodiment of the present invention.

FIG. 7C depicts a cross-sectional view C-C of the semiconductor structure after forming replacement metal gates, in accordance with an embodiment of the present invention.

### DETAILED DESCRIPTION

Aspects of the present invention provide a semiconductor structure that includes a self-aligned isolation layer separating the top source/drains of a top nanosheet field-effect transistor (FET) from the bottom source/drains of the bottom nanosheet FET of two stacked FETs. In various embodiments, the bottom nanosheet FET is wider than the top nanosheet FET. Using an area-selective atomic layer deposition (ALD) process, an oxide material for the isolation layer can grow from the exposed sidewalls of another oxide-based dielectric layer such as a middle dielectric isolation (MDI). Using the self-aligned selective growth process, the isolation layer can span the distance between two adjacent MDI to vertically separate the source/drains of a top FET from the source/drains of the bottom FET in stacked FET devices such as complimentary FETS (CFETs). A trimming operation can remove the wider center portion of the isolation layer after the selective ALD process creating concave top and bottom surfaces of the isolation layer. In embodiments, the isolation layer and the MDI are composed of oxide materials.

Using known epitaxy processes, the bottom source/drains are formed where during the epitaxial growth, an air gap is formed under the middle portion of the isolation layer. Similarly, using epitaxy, the top source/drains can be formed with an air gap over the middle portion of the isolation layer. The adjacent surfaces of the top source/drains, the isolation layer, and the bottom source/drains are curved or concave in the middle portions of these elements.

The source/drains of the top nanosheet FET connect to a top source/drain contact. After removing exposed portion of the isolation layer in the wider portion of the bottom nanosheet FET, the bottom source/drain contacts can be formed connecting to the bottom source/drains of the bottom nanosheet FET.

The following description with reference to the accompanying drawings is provided to assist in a comprehensive understanding of exemplary embodiments of the invention as defined by the claims and their equivalents. It includes various specific details to assist in that understanding but these are to be regarded as merely exemplary. Accordingly, those of ordinary skill in the art will recognize that various changes and modifications of the embodiments described herein can be made without departing from the scope and spirit of the invention. Some of the process steps, depicted, can be combined as an integrated process step. In addition, descriptions of well-known functions and constructions may be omitted for clarity and conciseness.

The terms and words used in the following description and claims are not limited to the bibliographical meanings but are merely used to enable a clear and consistent understanding of the invention. Accordingly, it should be apparent to those skilled in the art that the following description of exemplary embodiments of the present invention is provided for illustration purposes only and not for the purpose of limiting the invention as defined by the appended claims and their equivalents.

It is to be understood that the singular forms “a,” “an,” and “the” include plural referents unless the context dictates otherwise. Thus, for example, reference to “a component surface” includes reference to one or more of such surfaces unless the context dictates otherwise.

For purposes of the description hereinafter, terms such as “upper”, “lower”, “right”, “left”, “vertical”, “horizontal”, “top”, “bottom”, and derivatives thereof shall relate to the disclosed structures and methods, as oriented in the drawing figures. Terms such as “above”, “on”, “overlying”, “atop”, “on top”, “positioned on” or “positioned atop” mean that a first element, such as a first structure, is present on a second element, such as a second structure, wherein intervening elements, such as an interface structure may be present between the first element and the second element. The term “direct contact” or “contact” means that a first element, such as a first structure, and a second element, such as a second structure, are connected without any intermediary conducting, insulating, or semiconductor layers at the interface of the two elements.

In the interest of not obscuring the presentation of embodiments of the present invention, in the following detailed description, some processing steps or operations that are known in the art may have been combined for presentation and for illustration purposes and in some instances may have not been described in detail. In other instances, some processing steps or operations that are known in the art may not be described at all. It should be understood that the following description is rather focused on the distinctive features or elements of various embodiments of the present invention.

Detailed embodiments of the claimed structures and methods are disclosed herein. The method steps described below do not form a complete process flow for manufacturing integrated circuits on semiconductor chips. The present embodiments can be practiced in conjunction with the integrated circuit fabrication techniques for semiconductor chips and devices currently used in the art, and only so much of the commonly practiced process steps are included as are necessary for an understanding of the described embodiments. The figures represent cross-section portions of a semiconductor chip or a substrate, such as a semiconductor wafer during fabrication, and are not drawn to scale, but instead are drawn to illustrate the features of the described embodiments. Specific structural and functional details disclosed herein are not to be interpreted as limiting, but merely as a representative basis for teaching one skilled in the art to variously employ the methods and structures of the present disclosure. In the description, details of well-known features and techniques may be omitted to avoid unnecessarily obscuring the presented embodiments.

References in the specification to “one embodiment”, “other embodiment”, “another embodiment”, “an embodiment,” etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is understood that it is within the knowledge of one skilled in the art to affect such feature, structure, or characteristic in connection with other embodiments whether or not explicitly described.

Reference will now be made in detail to the embodiments of the present invention, examples of which are illustrated in the accompanying drawings, wherein like reference numerals refer to like elements throughout.

Deposition processes for materials, such as metal materials, dielectric materials, and sacrificial materials include but are not limited to chemical vapor deposition (CVD), physical vapor deposition (PVD), atomic layer deposition (ALD), molecular layer deposition (MLD), high-density plasma (HDP) deposition, or gas cluster ion beam (GCIB) deposition. Variations of CVD processes include but are not limited to, atmospheric pressure CVD (APCVD), low-pressure CVD (LPCVD), plasma enhanced CVD (PECVD), and metal-organic CVD (MOCVD), and combinations thereof may also be employed.

Removal, removing, or etching as used herein includes but is not limited to patterning using one of lithography, photolithography, an extreme ultraviolet (EUV) lithography process, or any other known semiconductor patterning process followed by one or more etching processes. Some examples of etching processes include but are not limited to the following processes, such as a dry etching process using a reactive ion etch (RIE) or ion beam etch (IBE), a wet chemical etch process, or a combination of these etching processes.

The terms “epitaxially growing and/or depositing” and “epitaxially grown and/or deposited” mean the growth of a semiconductor material on a deposition surface of a semiconductor material, which may be a seed semiconductor layer deposited on surface(s) of a semiconductor structure. The semiconductor material being grown has the same crystalline characteristics as the semiconductor material of the deposition surface. Examples of various epitaxial growth techniques include, for example, rapid thermal chemical vapor deposition (RTCVD), low-energy plasma deposition (LEPD), ultra-high vacuum chemical vapor deposition (UHVCVD), low-pressure chemical vapor deposition (LPCVD), atmospheric pressure chemical vapor deposition (APCVD) and molecular beam epitaxy (MBE).

Reference is now made to the figures. The figures provide schematic cross-sectional illustrations of semiconductor devices at intermediate stages of fabrication, according to one or more embodiments of the invention. The device provides schematic representations of the devices of the invention and is not to be considered accurate or limiting with regard to the device element scale.

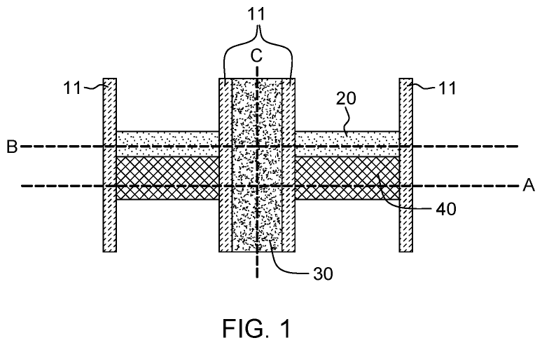

FIG. 1 depicts a top view of an illustration of a semiconductor design of a semiconductor device, in accordance with an embodiment of the present invention. As depicted, FIG. 1 includes gate structures 30, gate spacers 11, top FET 20, and bottom FET 40. Also, illustrated in FIG. 1 are the locations of cross-sectional views A-A, B-B, and C-C, where cross-sectional views A-A and B-B are perpendicular to gate structure 30 and cross-sectional views C-C are parallel to and bisect the center gate structure 30 in FIG. 1.

The semiconductor design illustrated in FIG. 1 depicts stacked FETs where top FET 20 is narrower than bottom FET 40. In various embodiments, the stacked FETs form a complementary FET (CFET). In various embodiments, top FET 20 is a PFET, and bottom FET 40 is an NFET. In other embodiments, top FET 20 is an NFET, and bottom FET 40 is a PFET. In an embodiment, top FET 20 and bottom FET 40 have the same polarity (e.g., both are NFETs or both are PFETs).

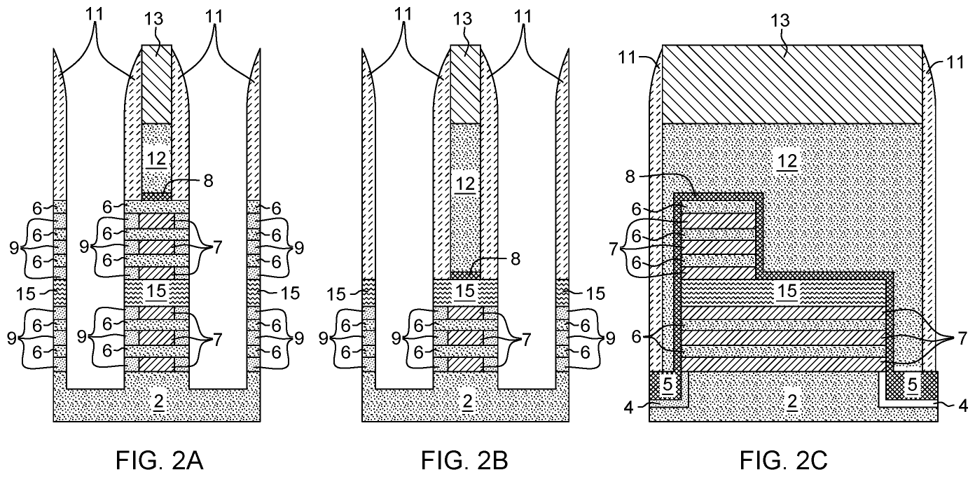

FIG. 2A depicts a cross-sectional view A-A of the semiconductor structure of FIG. 1 after the nanosheet stack recessing and dummy gate formation, in accordance with an embodiment of the present invention. As depicted, FIG. 2A includes the dummy gate structures with dummy gate material 12 over gate dielectric (not depicted), gate spacer 11, inner spacers 9 covered by hardmask (HM) 13, portions of a nanosheet stack (e.g. post fin recessing) which include channels 6, sacrificial material 7, and middle dielectric isolation (MDI) 15 with dielectric isolation 8 over the nanosheet stacks. FIG. 2A also includes portions of substrate 2 under inner spacers 9 and sacrificial material 7 and the recessed portions of substrate 2. The recessing of the nanosheet stack composed of alternating nanosheet layers of sacrificial material 7 (e.g., SiGe) and channels 6 (e.g., Si) and MDI 15 covered by dielectric isolation 8 also removes the top portion of substrate 2 between the remaining portions of the nanosheet stack.

After recessing of the nanosheet stack which may also be called fin recessing, the semiconductor structures of FIGS. 2A, 2B, and 2C are formed using known semiconductor dummy gate formation processes. The dummy gate structure, as depicted in FIG. 2A includes dummy gate material 12, gate spacer 11, inner spacers 9, and HM 13 can be formed dielectric isolation 8 and the top channel of channels 6.

In various embodiments, MDI 15 is composed of SiOC. In some embodiments, MDI 15 is composed of another oxide dielectric material. As depicted in FIG. 2A, MDI 15 separates the top nanosheet layers which include three layers of each of channels 6 and sacrificial material 7 from the bottom nanosheet layers which include two layers of each of channels 6 and three layers of sacrificial material 7. In other examples, different numbers of layers of channels 6 and sacrificial material 7 may be present above or below MDI 15.

FIG. 2B depicts a cross-sectional view B-B of the semiconductor structure of FIG. 1 after the nanosheet stack recessing and dummy gate formation, in accordance with an embodiment of the present invention. As depicted, FIG. 2B includes the elements of FIG. 2A without the portion of the nanosheet stack over MDI 15 and instead includes a larger portion of dummy gate material 12 above MDI 15 in the remaining portions of the nanosheet stack.

Using known semiconductor patterning and etching processes (e.g., RIE and/or IBE), the nanosheet recessing process as discussed above with respect to FIG. 2A occurs where the etching process stops at MDI 15. The etching process, as depicted in the semiconductor structure of FIG. 2B, removes the top layers of channels 6 and sacrificial material 7 leaving only the layers of channels 6 and sacrificial material 7 under MDI 15. No layers of the nanosheet stack are depicted on or above MDI 15 in FIG. 2B.

FIG. 2C depicts a cross-sectional view C-C of the semiconductor structure of FIG. 1 after nanosheet stack recessing and the dummy gate formation, in accordance with an embodiment of the present invention. As depicted, FIG. 2C includes the elements of FIG. 2A.

After nanosheet recessing as discussed above with reference to FIGS. 2B and 2A, in FIG. 2C, the bottom layers of sacrificial material 7 and channels 6 under MDI 15 are wider than the three top layers of sacrificial material 7 and channels 6 above MDI 15. One layer of sacrificial material 7 resides directly on MDI 15 and another layer of sacrificial material 7 resides directly under MDI 15. Dielectric isolation 8 covers the top surfaces and sidewalls of the top and bottom layers of the remaining portions of the nanosheet stack.

After using known semiconductor processes for dummy gate formation, in FIG. 2C, dummy gate material 12 is over dielectric isolation 8 and on portions of STI 5. Gate spacer 11 residing on portions of STI 5 surrounds dummy gate material 12 and HM 13. As depicted in FIG. 2C, the bottom layer of sacrificial material 7 resides on substrate 2.

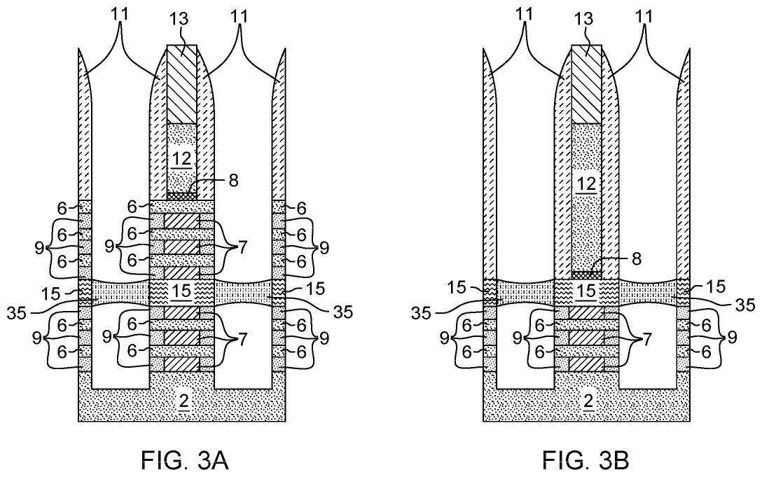

FIG. 3A depicts a cross-sectional view A-A of the semiconductor structure after selective growth of source/drain (S/D) S/D isolation layer 35 and S/D isolation layer 35 trimming, in accordance with an embodiment of the present invention. As depicted, FIG. 3A includes the elements of FIG. 2A with S/D isolation layer 35.

Using a known area selective ALD growth process, S/D isolation layer 35 can be grown on the exposed sidewall surfaces of MDI 15. The area-selective ALD growth process is selective to oxide materials and can grow an oxide material on an oxide layer. MDI 15, in various embodiments, is composed of SiOC but is not limited to this specific oxide material and in other embodiments, can be composed of another oxide material used in an isolation layer. S/D isolation layer 35 grows outward from the sidewalls of adjacent MDI 15. The height or thickness of the sidewalls of S/D isolation layer 35 is the same as the height of the sidewalls of MDI 15. Growing outward and laterally, the selectively grown oxide material of S/D isolation layer 35 forms a bridge or a connection suspended between the sidewalls of two facing and adjacent MDI 15 in the remaining portions of the nanosheet stack or stacks after nanosheet recessing discussed with reference to FIGS. 2A-C. In various embodiments, the self-aligned and selectively grown S/D isolation layer 35 is composed of an oxide dielectric material such as but not limited to SiO2.

In some cases, S/D isolation layer 35 can grow wider than either of the two MDI 15. When this occurs, S/D isolation layer 35 forms a wider, more rounded shape connection between the two adjacent MDI 15. In these cases, the vertical thickness of S/D isolation layer 35 in the middle portion of S/D isolation layer 35 can be greater than the vertical thickness or height of MDI 15.

In various embodiments, when S/D isolation layer 35 forms a thicker, rounder layer for the connection between two adjacent portions of MDI 15, a trimming process occurs. Trimmer a wider, more rounded bridge of S/D isolation layer 35 between two adjacent MDI 15 provides more space for the functional elements like source/drains of the semiconductor devices. For example, using a buffered oxide etch composed of a mixture of hydrofluoric acid and ammonium fluoride, S/D isolation layer 35 can be trimmed or thinned to a vertical thickness that is similar to or approximately the same as the vertical thickness of MDI 15. In various embodiments, the middle portion of the trimmed S/D isolation layer 35 is thinner than the sidewalls of S/D isolation layer 35 contacting MDI 15. In these embodiments, the top and bottom surfaces of S/D isolation layer 35 are slightly curved and concave after trimming. In other embodiments, the top and bottom surfaces of S/D isolation layer 35 are fairly flat after trimming.

In an embodiment, without trimming S/D isolation layer 35, the top and bottom surfaces of S/D isolation layer 35 are slightly convex (e.g., the middle portions of S/D isolation layer 35 are slightly thicker than the sidewalls of S/D isolation layer 35 contacting MDI 15).

FIG. 3B depicts a cross-sectional view B-B of the semiconductor structure after selective growth of S/D isolation layer 35 and S/D isolation layer 35 trimming, in accordance with an embodiment of the present invention. As depicted, FIG. 3B includes the elements of FIG. 2B with the addition of S/D isolation layer 35 formed using the processes discussed in detail with reference to FIG. 3A. As discussed above, the trimmed layer of S/D isolation layer 35 can have a middle portion that is one of thinner, thicker, or the same thickness of MDI 15. In some embodiments, the top surface and the bottom surface of S/D isolation layer 35 are concave.

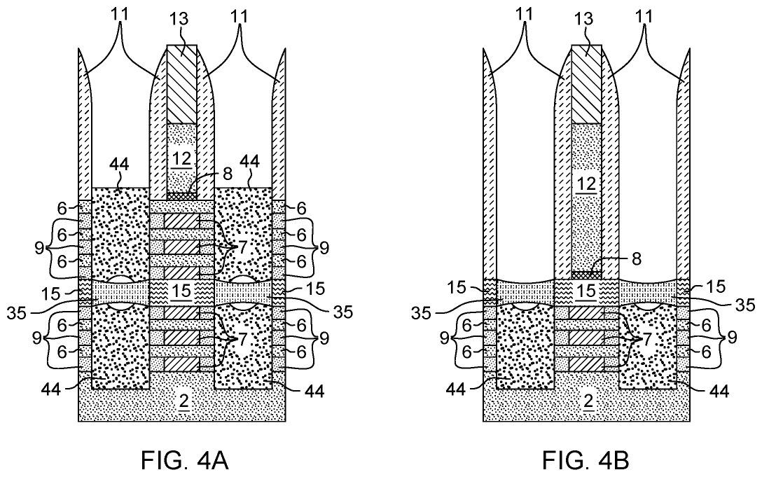

FIG. 4A depicts a cross-sectional view A-A of the semiconductor structure after epitaxial growth of source/drains (S/D) 44, in accordance with an embodiment of the present invention. As depicted, FIG. 4A includes the elements of FIG. 3A with the addition of S/D 44 above and below each of S/D isolation layer 35. In various embodiments, an air gap forms above the middle portions of the top and bottom surfaces of the center portion of S/D isolation layer 35. Each of the air gaps have a top or a bottom surface that is curved. The curved surface of each of the air gaps is rounded or concave providing an increased height of the air gap above the middle portions of S/D isolation layer 35 (e.g., the center of each of the air gaps above and below the center portion of S/D isolation layer 35 are further from the surface of S/D isolation layer 35 than the outer edges of each of the air gaps contacting S/D isolation layer 35). With the air gap, the top and bottom surfaces of S/D 44 adjacent to the air gap above and below the middle portions of S/D isolation layer 35 are concave.

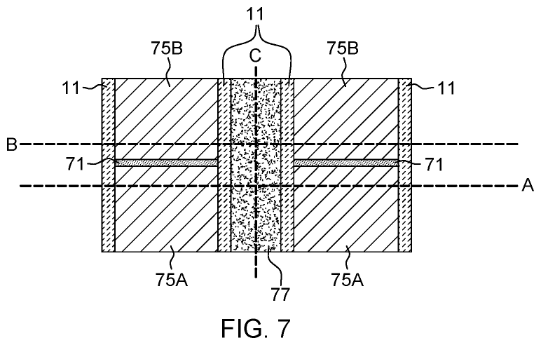

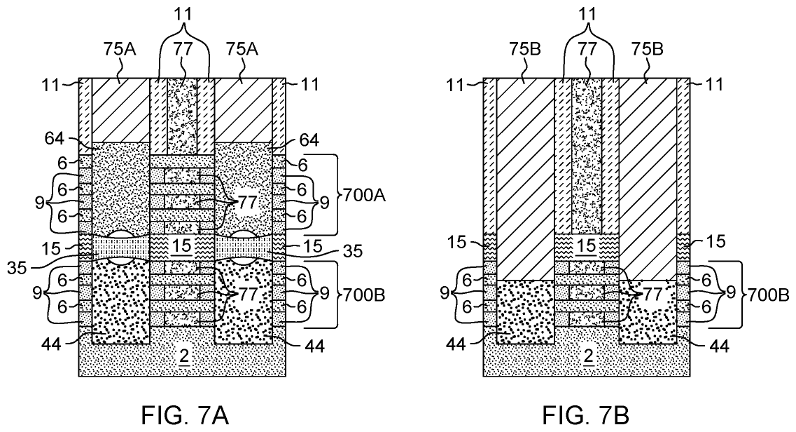

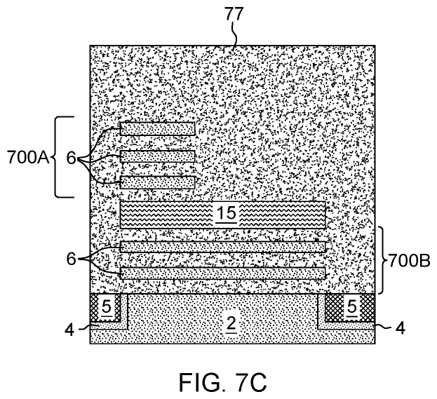

Using known epitaxy, S/D 44 can be grown from channels 6 and substrate 2. The air gap can naturally form above and below the oxide surfaces of S/D isolation layer 35 during the epitaxial growth of S/D 44 from the sidewalls of channels 6. As known to one skilled in the art, the air gaps may improve the effective capacitance of the completed stacked FET devices depicted later in FIGS. 7A, 7B, and 7C.

Each of the four of S/D 44 in FIG. 4A contacts the air gap and portions of S/D isolation layer 35. In various embodiments, S/D 44 is a doped source/drain for a NFET. For example, S/D 44 can be doped with phosphorus (P) or any other suitable n-type doping material In these cases, S/D 44 can be SiP, for example. In some embodiments, S/D 44 is a doped source/drain for a PFET. In this example, S/D 44 (e.g., SiGeB) can be doped with boron (B) or any other suitable p-type doping material. In one embodiment, S/D 44 is not doped.

FIG. 4B depicts a cross-sectional view B-B of the semiconductor structure after epitaxial growth of source/drains 44, in accordance with an embodiment of the present invention. As depicted, FIG. 4B includes the elements of FIG. 3B with an air gap under the middle of S/D isolation layer 35 and S/D 44 below the air gap and contacting portions of S/D isolation layer 35. As depicted in FIG. 4B, two portions of S/D 44 can be formed in FIG. 4B under S/D isolation layer 35 and the air gap.

S/D 44 in FIG. 4B forms by the epitaxial growth processes previously discussed with reference to FIG. 4A and with the same possible doping options discussed above (i.e., n-doped, p-doped, or undoped S/D 44). The top surface of S/D 44 under the air gap is concave (e.g., lower surface in the middle of S/D 44).

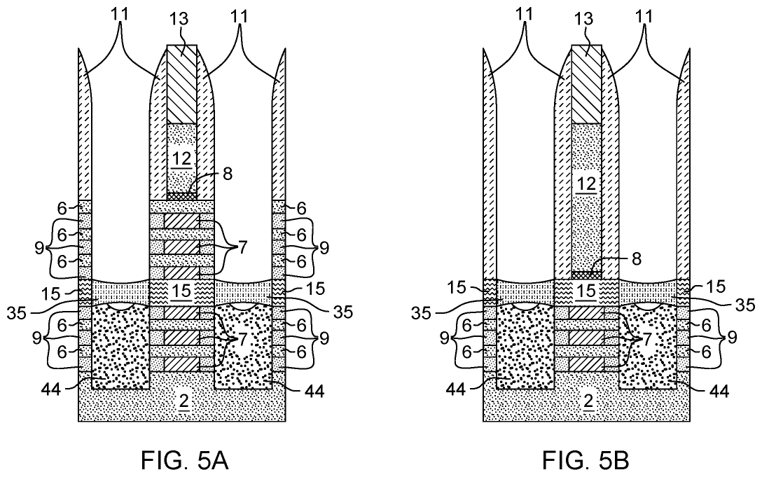

FIG. 5A depicts a cross-sectional view A-A of the semiconductor structure after removal of the top two S/D 44, in accordance with an embodiment of the present invention. As depicted, FIG. 5A includes the elements of FIG. 4A without the two top S/D 44 above S/D isolation layer 35. Using a directional etching process, such as RIE, the two top S/D 44 over S/D isolation layer 35 can be removed. The etching process stops at the top surface of S/D isolation layer 35.

FIG. 5B depicts a cross-sectional view B-B of the semiconductor structure after the removal of the top two S/D 44 depicted in FIG. 5A, in accordance with an embodiment of the present invention. As depicted, FIG. 5B is the same as FIG. 4B.

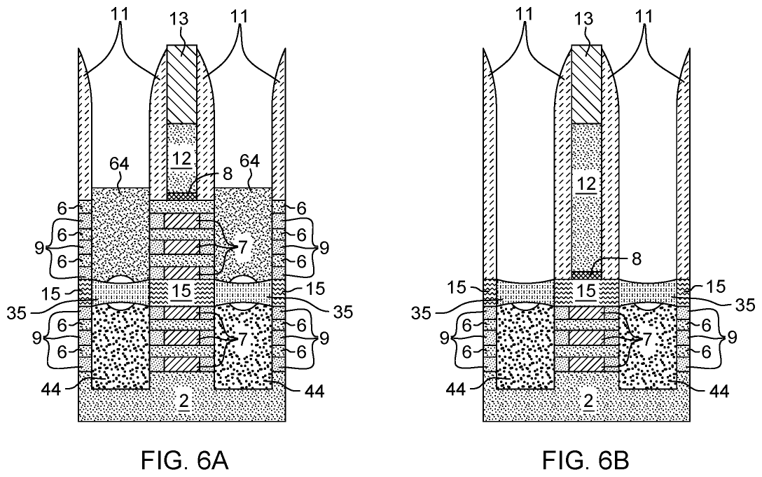

FIG. 6A depicts a cross-sectional view A-A of the semiconductor structure after the growth of S/D 64, in accordance with an embodiment of the present invention. As depicted, FIG. 6A includes the elements of FIG. 5A with the addition of S/D 64.

Using epitaxy, a portion of S/D 64 forms over each of the two portion of S/D isolation layer 35. S/D 64, similar to S/D 44 discussed above with reference to FIG. 4A, can doped with either a p-type dopant, an n-type dopant, or remain undoped.

In various embodiments, when S/D 44 is doped with an n-type dopant for an NFET and, S/D 64 is doped with a p-type dopant for a PFET. In other embodiments, S/D 44 includes a p-type dopant and S/D 64 includes an n-type dopant. In some embodiments, both S/D 44 and S/D 64 have the same type dopant or are both undoped.

With the air gap, the bottom surfaces of S/D 64 adjacent to the air gap above and below the middle portions of S/D isolation layer 35 are concave (e.g., with an air gap under the middle portion of S/D 64 creating a space where a crescent-like portion of S/D 64 is not present).

FIG. 6B depicts a cross-sectional view B-B of the semiconductor structure after top source/drain growth depicted in FIG. 6A, in accordance with an embodiment of the present invention. As depicted, FIG. 6B is the same as FIG. 5B.

FIG. 7 is a top view of the semiconductor structure after forming replacement metal gate 77, top source/drain contacts 75A, isolation 71, and bottom source/drain contacts 75B, in accordance with an embodiment of the present invention. As depicted, FIG. 7 includes replacement metal gate 77 with gate spacers 11, two top source/drain contacts 75A surrounding a top portion of replacement metal gate 77 with gate spacers 11, two bottom source/drain contacts 75B surrounding a bottom portion of replacement metal gate 77 with gate spacers 11, and isolation 71 separating top source/drain contacts 75A from bottom source/drain contacts 75B. Isolation 71 can be a self-aligned isolation layer. Also, illustrated are the locations of cross-sectional views A-A and B-B depicted as horizontal lines, and cross-sectional view C-C depicted with a vertical line in FIG. 7.

FIG. 7A depicts a cross-sectional view A-A of the semiconductor structure of FIG. 7 after forming replacement metal gate 77 and source/drain contacts 75A, in accordance with an embodiment of the present invention. As depicted, FIG. 7A includes the elements of FIG. 6A without dummy gate material 12, sacrificial material 7, and HM 13, and after forming replacement metal gate 77 and top source/drain contact 75A. Also, illustrated in FIG. 7A are top FET 700A and bottom FET 700B.

Using known replacement metal gate formation processes, dummy gate material 12, sacrificial material 7, and HM 13 are removed and replacement metal gate 77 can be formed. As known to one skilled in the art, replacement metal gate 77 can include a gate electrode material, one or more work function materials, a gate dielectric under the gate electrode material, and one or more gate contacts (not depicted in FIG. 7A, 7B, or 7C).

After forming replacement metal gate 77, using known contact formation processes (e.g., patterning, etching, contact metal deposition, and chemical-mechanical polishing (CMP)) top source/drain contacts 75A can be formed with known contact metals (e.g., W, Cu, Ru). As depicted, FIG. 7A includes top source/drain contact 75A connecting to S/D 64 of the top FET 700A of the semiconductor structure.

In various embodiments, the semiconductor structure of FIG. 7A is a portion of a CFET when S/D 64 of top FET 700A is doped with one type of dopant (e.g., n-type dopant) and S/D 44 of bottom FET 700B is doped with the second type of dopant (e.g., p-type dopant). For example, S/D 64 of top FET 700A is doped with a p-type dopant such as phosphorous to form a PFET, and S/D 44 of bottom FET 700B is doped with an n-type dopant such as boron to form an NFET of the stacked FETs forming a CFET. In other embodiments, top FET 700A with S/D 64 is an NFET, and bottom FET 700B with S/D 44 is a PFET in the CFET. As previously discussed, the air gap depicted both above and below the middle or central portion of S/D isolation layer 35 decreases the effective capacitance of the CFET and improves the electrical performance of the CFET.

In other examples, the top FET with S/D 64 and the bottom FET with S/D 44 have the same type of doping (e.g., n-type, p-type, or no doping). In these examples, the semiconductor structure of FIG. 7A can be a portion of two stacked FETs. In other examples, more than two FETs are stacked in the semiconductor structure. For example, three FETs can be stacked.

FIG. 7B depicts a cross-sectional view B-B of the semiconductor structure of FIG. 7 after forming replacement metal gate 77 and bottom source/drain contacts 75B, in accordance with an embodiment of the present invention. As depicted, FIG. 7B includes the elements of FIG. 6B without a portion of S/D isolation layer 35 over S/D 44, dummy gate material 12, sacrificial material 7, and HM 13, and after forming replacement metal gate 77 and top source/drain contact 75B. Also, depicted in FIG. 7B is bottom FET 700B.

Using the known semiconductor processes discussed above for replacement metal gate 77 formation, replacement metal gate 77 forms between and contacting gate spacers 11 and between channels 6 and MDI 15.

Using known an etching process, such as RIE, S/D isolation layer 35 can be removed above S/D 44 and the contact metal can be deposited on the exposed top surface of S/D 44. A CMP may remove the excess contact metal to form bottom S/D contact 75B. Bottom contact 75B resides directly on S/D 44 and is between gate spacers 11 on replacement metal gate 77. As depicted, FIG. 7B illustrates S/D 44 of the bottom FET 700B. In some embodiments, isolation layer 35 is between two adjacent stacked FETs.

S/D 64 is not present in FIG. 7B. Top FET 700A is not present in FIG. 7B.

FIG. 7C depicts a cross-sectional view C-C of the semiconductor structure of FIG. 7 after forming replacement metal gates, in accordance with an embodiment of the present invention. As depicted, FIG. 7C includes substrate 2, STI 5, liner 4, replacement metal gate 77, channels 6, MDI 15, top FET 700A, and bottom FET 700B.

As depicted, top FET 700A residing on a portion of MDI 15 is narrower than bottom FET 700B directly under MDI 15. Bottom FET 700B resides on a portion of substrate 2. As previously discussed, in various embodiments, when the narrower top FET 700A is a PFET and the wider bottom FET 700B is an NFET, the stacked FETs can be CFET. In other embodiments, top FET 700A is an NFET, and bottom FET 700B is a PFET.

As previously discussed, in other embodiments, when the stacked FETs have the same type of doping (e.g., two or more NFETs can stacked). The stacked FETs can have different types of polarity (e.g., a PFET and an NFET or vice versa) as in a complementary FET (CFET).

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the invention. The terminology used herein was chosen to best explain the principles of the embodiment, the practical application or technical improvement over technologies found in the marketplace, or to enable others of ordinary skill in the art to understand the embodiments disclosed herein.

What is claimed is:

1. A semiconductor structure comprising:
an isolation layer contacting a top source/drain and a bottom source/drain; and
an air gap between a middle portion of each of the top source/drain, the bottom source/drain, and the isolation layer.

2. The semiconductor structure of claim 1, wherein the top source/drain, the bottom source/drain, and the isolation layer are vertically aligned.

3. The semiconductor structure of claim 1, wherein the isolation layer has a top surface and a bottom surface that are concave.

4. The semiconductor structure of claim 1, wherein the isolation layer sidewalls contact a middle dielectric isolation, wherein the isolation layer and the middle dielectric isolation are composed of different oxide dielectric materials.

5. The semiconductor structure of claim 4, wherein the middle dielectric isolation resides between a plurality of channels of a top field-effect transistor (FET) and a plurality of channels of a bottom FET.

6. The semiconductor structure of claim 4, wherein the bottom FET is wider than the top FET, further comprising:
a gate structure around the plurality of channels of the top FET and the bottom FET; and
a source/drain contact directly on the top source/drain;

7. A semiconductor structure comprising:
a top field-effect transistor (FET) on a portion of a bottom FET;
a middle dielectric isolation layer over a top surface of a gate of the bottom FET;
an isolation layer connecting sidewalls of adjacent portions of the middle dielectric isolation, wherein the isolation layer separates one or more top source/drains of the top FET from one or more bottom source/drains of the bottom FET.

8. The semiconductor structure of claim 7, further comprising:
a gate structure around the plurality of channels of the top FET and the bottom FET;
a top source/drain contact contacting each of the one or more top source/drains; and
a bottom source/drain contact contacting each of the one or more bottom source/drains not under a portion of the top FET.

9. The semiconductor structure of claim 7, wherein the isolation layer has a top surface and a bottom surface that are each concave.

10. The semiconductor structure claim 7, wherein the isolation layer sidewalls have a same height as the height of sidewalls of the middle dielectric isolation.

11. The semiconductor structure of claim 7, wherein the isolation layer is composed of a different oxide material than the middle dielectric isolation.

12. The semiconductor structure of claim 7, wherein the one or more bottom source/drain top surfaces contact an air gap, wherein the one or more bottom source/drain top surfaces are curved.

13. The semiconductor structure of claim 7, wherein:
the bottom FET is wider than the top FET; and
each of the bottom source/drain contacts contacts the sidewalls of the middle dielectric isolation.

14. The semiconductor structure of claim 7, wherein the top FET is an NFET and the bottom FET is a PFET.

15. The semiconductor structure of claim 7, wherein the top FET is a PFET and the bottom FET is an NFET.

16. A method of forming a semiconductor structure comprising:
recessing portions of a nanosheet stack;
forming dummy gates;
selectively growing an isolation layer from the exposed sidewalls of two or more middle dielectric layers;
trimming the isolation layer;
forming a first type of source/drains above and below the isolation layer using epitaxial growth from a first plurality of channels, wherein an air gap is formed above and below a middle portion of the isolation layer;
removing portions of the first type of source/drains above the isolation layer;
forming a second type of source/drains over the portion of isolation layer using epitaxial growth from a portion of the plurality of channels;
forming replacement metal gates;
removing exposed portions of the isolation layer; and
forming a source/drain contact over each of the first type of source/drains and exposed surfaces of the second type of source/drains.

17. The method of claim 16, wherein the nanosheet stack includes a middle dielectric material composed of an oxide material between two layers of sacrificial material, and wherein three layers of nanosheet channels reside above a middle dielectric isolation and two layers of nanosheet channels are below the middle dielectric isolation.

18. The method of claim 16, wherein trimming the isolation layer forms concave top and bottom surfaces of the isolation layer.

19. The method of claim 16, wherein forming the first type of source/drains over the portion of isolation layer include forming an air gap between a middle portion of the isolation layer and the first type of source/drains.

20. The method of claim 19, wherein the first type of source/drains have a concave surface adjacent to the air gap.
